(19) United States
(12) Patent Application Publication
(10) Pub. No.: US 2008/0142796 A1
(43) Pub. Date: Jun. 19, 2008

(54) ZnO diode and method of forming the same

(75) Inventors: Dong-hun Kang, Yongin-si (KR); I-hun Song, Seongnam-si (KR); Chang-Jung Kim, Yongin-si (KR); Young-soo Park, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/980,454

(22) Filed: Oct. 31, 2007

(30) Foreign Application Priority Data
Dec. 13, 2006 (KR) 10-2006-0127306

(51) Int. Cl. H01L 29/10; H01L 21/16

(52) U.S. Cl. 257/43; 438/104; 257/E29.043

(57) ABSTRACT

A zinc oxide (ZnO) group and method of forming the same are provided. The ZnO group diode may include a first electrode and a second electrode that are separated from each other, and an active layer formed of MₓIn₁₋ₓZnO (wherein “M” is a Group III metal) between the first electrode and the second electrode. The first electrode may have a work function lower than the active layer. The second electrode may have a work function higher than the active layer.

### PRIORITY STATEMENT

This application claims the benefit of priority under 35 U.S.C. §119 from Korean Patent Application No. 10-2006-0127306, filed on Dec. 13, 2006, in the Korean Intellectual Property Office, the content of which is incorporated herein by reference in its entirety.

### BACKGROUND

1. Field

Example embodiments relate to a ZnO group diode and method of forming the same. Other example embodiments relate to a transparent ZnO group diode that includes a Group III element and is stable to heat and visible light and method of forming the same.

2. Description of the Related Art

Semiconductor diodes having rectifying and switching characteristics may be used in a variety of fields. Switching diodes may be used in memory devices and transistors. A memory device having a diode formed of indium zinc oxide (InZnO) and a resistor as a unit cell has been recently developed.

FIG. 1 is a graph illustrating thermal characteristics of a conventional transistor that uses a channel formed of InZnO between a source and a drain.

Referring to FIG. 1, InZnO does not function at a temperature above 200° C. In other words, an InZnO channel is thermally unstable at a temperature above 150° C.

FIG. 2 is a graph illustrating the sensitivity of a conventional transistor that includes an InZnO channel with respect to visible light.

Referring to FIG. 2, the transistor that includes the InZnO channel may be easier to turn on by visible light. In other words, an InZnO channel easily reacts with visible light.

As such, the use of InZnO in a switching device may be undesirable due to the instability of InZnO to heat and visible light.

### SUMMARY

Example embodiments relate to a ZnO group diode and method of forming the same. Other example embodiments relate to a transparent ZnO group diode that includes a Group III element and is stable to heat and visible light and method of forming the same.

According to example embodiments, there is provided a ZnO group diode including a first electrode and a second electrode that are separated from each other and an active layer formed of MₓIn₁₋ₓZnO (wherein M is a Group III metal) between the first electrode and the second electrode. The first electrode may have a work function lower than the active layer. The second electrode may have a work function higher than the active layer. X ranges from 0.2 to 0.8.

The Group III metal may be one selected from the group including Ga, Al, Ti and combinations thereof.

The first electrode may be formed of a material selected from the group including Ti, Al, Ca and Li and combinations thereof. The second electrode may be formed of a material selected from the group including Pt, Mo, W, Ir and combinations thereof.

According to example embodiments, there is provided a ZnO group diode including an active layer formed of MₓIn₁₋ₓZnO (wherein M is a Group III metal), a first electrode and a second electrode, wherein the first and second electrodes are separated from each other on the active layer. The first electrode may have a work function lower than the active layer. The second electrode may have a work function higher than the active layer.

According to example embodiments, there is provided a method of forming a ZnO group diode including forming a first electrode and a second electrode separated from each other and forming an active layer contacting the first electrode and the second electrode. The active layer may be formed of MxIn1-xZnO wherein M represents a Group III metal. The first electrode may have a work function lower than the active layer. The second electrode may have a work function higher than the active layer. The active layer may be formed between the first electrode and the second electrode. The Group III metal may be at least one selected from the group including gallium (Ga), aluminum (Al), titanium (Ti) and combinations thereof.

### BRIEF DESCRIPTION OF THE DRAWINGS

Example embodiments will be more clearly understood from the following detailed description taken in conjunction with the accompanying drawings. FIGS. 1-5 represent non-limiting, example embodiments as described herein.

FIG. 1 is a graph illustrating thermal characteristics of a conventional transistor that includes an InZnO channel between a source electrode and a drain electrode;

FIG. 2 is a graph illustrating the sensitivity of a conventional transistor that uses an InZnO channel with respect to visible light;

FIG. 3 is a diagram illustrating a cross-sectional view of a GaInZnO diode according to example embodiments;

FIG. 4 is a graph illustrating current-voltage (I-V) characteristics of a GaInZnO diode according to example embodiments; and

FIG. 5 is a diagram illustrating a cross-sectional view of a GaInZnO diode according to example embodiments.

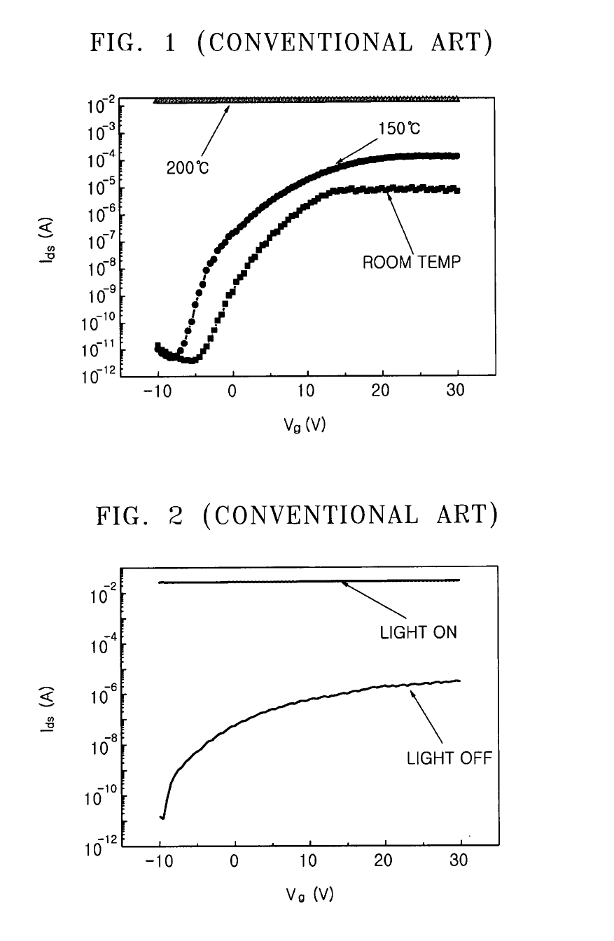

### DETAILED DESCRIPTION OF EXAMPLE EMBODIMENTS

Various example embodiments will now be described more fully with reference to the accompanying drawings in which some example embodiments are shown. In the drawings, the thicknesses of layers and regions may be exaggerated for clarity.

Detailed illustrative embodiments are disclosed herein. However, specific structural and functional details disclosed herein are merely representative for purposes of describing example embodiments. This invention may, however, may be embodied in many alternate forms and should not be construed as limited to only example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of example embodiments.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope. It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various aspects will be described in detail with reference to the attached drawings. However, the present invention is not limited to example embodiments described.

Example embodiments relate to a ZnO group diode and method of forming the same. Other example embodiments relate to a transparent ZnO group diode that includes a Group III element and is stable to heat and visible light and method of forming the same.

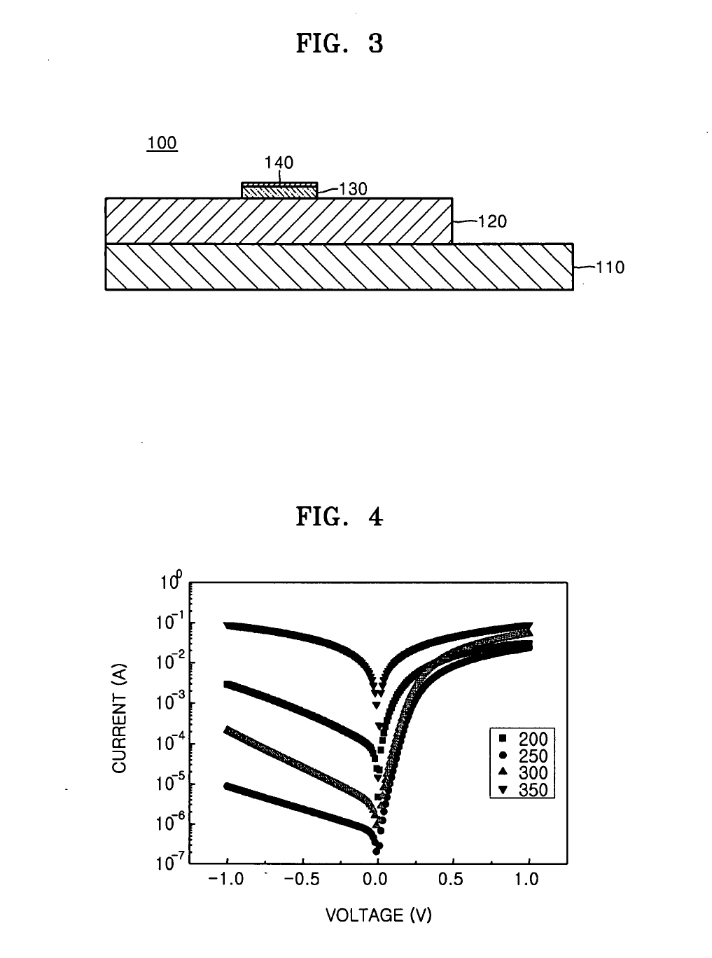

FIG. 3 is a diagram illustrating a cross-sectional view of a GaInZnO diode according to example embodiments.

Referring to FIG. 3, an active layer 120 may be formed on a lower electrode 110. An upper electrode 130 may be formed on the active layer 120. A passivation layer 140 may be formed on the upper electrode 130. The active layer 120 may be formed of GaₓIn₁₋ₓZnO wherein the following expression 0.2≦×≦0.8 is satisfied. Because gallium (Ga) forms a stronger chemical bond with oxygen than indium (In), the ratio of the atomic number of Ga to the sum of the atomic numbers of Ga and In (i.e., Ga/(Ga+In)) may be 20% to 80%. If the ratio of Ga to the sum of the atomic numbers of Ga and In exceeds 80% in the active layer 120, the active layer 120 may function as an insulating layer because the number of carriers is reduced. If the ratio of Ga to the sum of the atomic numbers of Ga and In is less than 20%, the active layer 120 may have a structure that is unstable to heat. The Ga atom may be replaced by a Group III atom (e.g., aluminum (Al), titanium (Ti) or combinations thereof), which has a higher heat of formation with respect to an oxide.

The active layer 120 may be formed having a thickness of approximately 1000 Å. The active layer 120 may be formed using an RF sputtering method, a chemical vapor deposition (CVD) method, an ion beam deposition method or the like.

The lower electrode 110 may be formed of a material having a higher work function than the active layer 120. The material may be a metal or a transition metal (e.g., platinum (Pt), molybdenum (Mo), tungste n (W), iridium (Ir) or combinations thereof.

The upper electrode 130 may be formed of a material having a lower work function than the active layer 120 (e.g., titanium (Ti), aluminum (Al), calcium (Ca) or lithium (Li) or combinations thereof).

The passivation layer 140 prevents (or reduces) oxidation of the upper electrode 130. The passivation layer 140 may be formed of platinum (Pt), ruthenium (Ru), gold (Au), tungsten (W) and combinations thereof.

If the lower electrode 110 and the upper electrode 130 are formed of a transparent metal (e.g., the lower electrode 110 is formed of Pt and the upper electrode 130 is formed of Ti), then a transparent diode may be manufactured.

FIG. 4 is a graph illustrating current-voltage (I-V) characteristics of a GaInZnO diode according to example embodiments. The GaInZnO diode of FIG. 4 has an active layer formed of GaInZnO, a diameter of 100 μm, a thickness of 1000 Å and the atomic ratio of Ga:In is 1:1.

Referring to FIG. 4, the GaInZnO diode exhibits diode characteristics even if the temperature of the GaInZnO diode is 300° C. That is, if a positive voltage is applied to the GaInZnO diode, the GaInZnO diode has a current approximately three orders higher than a current if a negative voltage is applied. The stable performance of a diode having the active layer 120 formed of GaInZnO at a higher temperature is due to the substantially strong bond between the Ga atom and oxygen. If the active layer 120 is used as a channel of a transistor, the active layer 120 is resistant to light.

The GaInZnO diode 100 according to example embodiments is a Schottky barrier type diode. In a Schottky barrier type diode, if a positive voltage is applied to the upper electrode 130, current flows towards the lower electrode 110. If a positive voltage is applied to the lower electrode 110, current does not easily flow towards the upper electrode 130. The GaInZnO diode 100 is stable to heat and visible light.

If the GaInZnO diode 100 according to example embodiments is used as a switching device in a resistance memory device, a thermally stable resistance memory device may be manufactured.

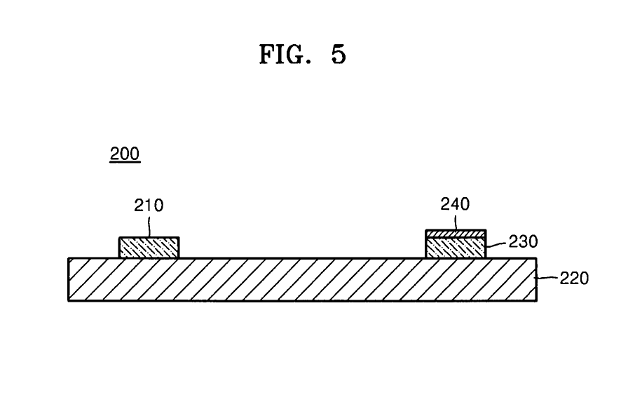

FIG. 5 is a diagram illustrating a cross-sectional view of a GaInZnO diode according to example embodiments.

Referring to FIG. 5, a first electrode 210 and a second electrode 230, which are separated from each other, may be formed on an active layer 220. A passivation layer 240 may be formed on the second electrode 230. The active layer 220 may be formed of GaₓIn₁₋ₓZnO wherein the expression 0.2≦×≦0.8 is satisfied. The ratio of the atomic number of Ga to the sum of the atomic numbers of Ga and In (i.e., Ga/(Ga+In)) may be 20% to 80%. If the ratio of Ga to the sum of the atomic numbers of Ga and In exceeds 80% in the active layer 220, the active layer 220 may function as an insulating layer because the number of carriers is reduced. If the ratio of Ga to the sum of the atomic numbers of Ga and In is less than 20%, the active layer 220 may have a structure that is unstable to heat. The Ga atom may be replaced by a Group III atom (e.g., aluminum (Al), titanium (Ti) and combinations thereof), which has a higher heat of formation with respect to an oxide.

The first electrode 210 may be formed of a material having a higher work function than the active layer 220. The material may be a metal or transition metal (e.g., Pt, Mo, W, Ir and combinations thereof.

The second electrode 230 may be formed of a material having a lower work function than the active layer 220. The material may be formed of a metal (e.g., Ti, Al, Ca, Li and combinations thereof). The passivation layer 240 prevents (or reduces) oxidation of the second electrode 230. The passivation layer 240 may be formed of Pt.

The GaInZnO diode 200 according to example embodiments has substantially identical characteristics to the GaInZnO diode 100. Thus, a detailed description thereof will not be repeated for the sake of brevity.

As described above, a diode with an active layer formed of GaInZnO according to example embodiments is stable to heat and visible light. As such, the GaInZnO diode may be used as a switching device. The GaInZnO diode may be used in a transparent display apparatus if the GaInZnO diode is formed using transparent electrodes.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

What is claimed is:

1. A ZnO group diode, comprising:
a first electrode and a second electrode separated from each other; and
an active layer between the first electrode and the second electrode, said active layer formed of MₓIn₁₋ₓZnO with M representing a Group III metal,
wherein the first electrode has a work function lower than the active layer and the second electrode has a work function higher than the active layer.

2. The ZnO group diode of claim 1, wherein the Group III metal is at least one selected from the group consisting of gallium (Ga), aluminum (Al), titanium (Ti) and combinations thereof.

3. The ZnO group diode of claim 2, wherein x ranges from 0.2 to 0.8.

4. The ZnO group diode of claim 1, wherein the first electrode is formed of a material including a metal.

5. The ZnO group diode of claim 4, wherein the metal is selected from the group consisting of titanium (Ti), aluminum (Al), calcium (Ca), lithium (Li) and combinations thereof.

6. The ZnO group diode of claim 1, wherein the second electrode is formed of a material including a metal.

7. The ZnO group diode of claim 6, wherein the metal is selected from the group consisting of platinum (Pt), molybdenum (Mo), tungsten (W), iridium (Ir) and combinations thereof.

8. A ZnO group diode, comprising:
an active layer formed of MₓInₗ₋ₓZnO with M representing a Group III metal; and
a first electrode and a second electrode separated from each other on the active layer,
wherein the first electrode has a work function lower than the active layer and the second electrode has a work function higher than the active layer.

9. The ZnO group diode of claim 8, wherein the Group III metal is at least one selected from the group consisting of gallium (Ga), aluminum (Al), titanium (Ti) and combinations thereof.

10. The ZnO group diode of claim 9, wherein x ranges from 0.2 to 0.8.

11. The ZnO group diode of claim 8, wherein the first electrode is formed of a material including a metal.

12. The ZnO group diode of claim 11, wherein the metal is selected from the group consisting of titanium (Ti), aluminum (Al), calcium (Ca), lithium (Li) and combinations thereof.

13. The ZnO group diode of claim 8, wherein the second electrode is formed of a material including a metal.

14. The ZnO group diode of claim 13, wherein the metal is selected from the group consisting of platinum (Pt), molybdenum (Mo), tungsten (W), iridium (Ir) and combinations thereof.

15. A method of forming a ZnO group-diode, comprising:
forming a first electrode and a second electrode separated from each other; and
forming an active layer contacting the first electrode and the second electrode, said active layer formed of MₓIn₁₋ₓZnO with M representing a Group III metal,
wherein the first electrode has a work function lower than the active layer and the second electrode has a work function higher than the active layer.

16. The method according to claim 15, wherein the active layer is formed between the first electrode and the second electrode.

17. The method according to claim 15, wherein the Group III metal is at least one selected from the group consisting of gallium (Ga), aluminum (Al), titanium (Ti) and combinations thereof.

18. The method according to claim 17, wherein x ranges from 0.2 to 0.8.

19. The method according to claim 15, wherein the first electrode and the second electrode are formed on the active layer.

20. The method according to claim 19, wherein the Group III metal is at least one selected from the group consisting of gallium (Ga), aluminum (Al), titanium (Ti) and combinations thereof.

21. The method according to claim 20, wherein x ranges from 0.2 to 0.8.
